(19) United States
(12) Patent Application Publication
(10) Pub. No.: US 2024/0077589 A1
(43) Pub. Date: Mar. 7, 2024

(54) SCANNING APPARATUS PLACEMENT METHOD, APPARATUS AND STORAGE MEDIUM

(71) Applicant: SUTENG INNOVATION TECHNOLOGY CO., LTD., Shenzhen (CN)

(72) Inventor: Huazhou CHEN, Shenzhen (CN)

(73) Assignee: SUTENG INNOVATION TECHNOLOGY CO., LTD., Shenzhen (CN)

(21) Appl. No.: 18/232,334

(22) Filed: Aug. 9, 2023

(30) Foreign Application Priority Data
Sep. 1, 2022 (CN) 202211064537.5

(51) Int. Cl. G01S 7/481; G01S 17/89; G02B 26/12

(52) U.S. Cl. CPC G01S 7/4817; G01S 17/89; G02B 26/12

(57) ABSTRACT

The present disclosure provides a scanning apparatus placement method, an apparatus and a storage medium. The method includes: establishing a calculation model of a receiving cross section of a second scanning surface; based on the calculation model of a receiving cross section, within a preset rotation range of a first scanning apparatus and an allowable range of a first distance, obtaining a distribution set of sizes of cross sections corresponding to a size of the receiving cross section, an angle of the first scanning apparatus, and a first distance; and selecting a corresponding first distance from the distribution set of sizes of cross sections, when the sizes of the receiving cross sections are symmetrically distributed relative to an angle of the first scanning apparatus.

### CROSS-REFERENCE TO RELATED APPLICATION

The present application claims the benefit of priority to Chinese Patent Application No. 202211064537.5, filed on Sep. 1, 2022, which is hereby incorporated by reference in its entirety.

### TECHNICAL FIELD

The present disclosure relates to the technical field of optical detection, and in particular, to a scanning apparatus placement method, an apparatus and a storage medium.

### BACKGROUND

LiDAR is a commonly used ranging sensor. By virtue of characteristics of long detection distance, high resolution, and low vulnerability to environmental interference, LiDARs are widely used in fields such as smart robots, unmanned aerial vehicles, and autonomous driving. A LiDAR usually measures a distance based on Time of Flight (TOF) by emitting laser pulses to an external scene in one emission direction and receiving an echo beam generated after the laser pulses are reflected by an object in the external scene. By measuring the time delay of the echo beam, a distance between the object and the LiDAR in the emission direction can be calculated. By dynamically adjusting outgoing directions of laser beams, information about distances between objects at different azimuths and the LiDAR can be detected, thereby building a model of three-dimensional space.

LiDAR can directly fast image three-dimensional space with high precision, and therefore, has become one of the most core sensors in existing autonomous driving technologies. An existing mainstream LiDAR includes a first scanning apparatus and a second scanning apparatus. The first scanning apparatus has a first scanning surface, and the second scanning apparatus has a second scanning surface. On an optical path of an echo beam, the first scanning apparatus is located upstream of an optical path of the second scanning apparatus, the first scanning surface is configured to reflect a laser beam incident on the first scanning surface to the second scanning surface, to implement scanning of the laser beam. When the laser beams are at a center of a horizontal field of view, a size of a receiving cross section of the second scanning surface is the maximum; or when the laser beams are on left and right sides of the horizontal field of view, a size of a receiving cross section of the second scanning surface is reduced, but sizes of corresponding receiving cross sections on the left and right sides are usually asymmetrical, so that the entire LiDAR has different ranging performance on the left and right sides horizontally, thereby deteriorating point clouds.

### SUMMARY

The present disclosure aims to provide a scanning apparatus placement method, an apparatus, and a storage medium, to resolve a technical problem that a point cloud of LiDAR deteriorates due to unreasonable placement positions of an existing first scanning apparatus and second scanning apparatus.

According to a first aspect, this application provides a scanning apparatus placement method, applied to a first scanning apparatus and a second scanning apparatus on the same horizontal plane, where the first scanning apparatus has a first scanning surface, and the second scanning apparatus has a second scanning surface, where the method is used to determine a first distance between a center of the first scanning surface and a center of the second scanning surface in a first direction, and includes: establishing a calculation model of a receiving cross section of the second scanning surface; based on the calculation model of a receiving cross section, within a preset rotation range of the first scanning apparatus and an allowable range of the first distance, obtaining a distribution set of sizes of cross sections corresponding to an angle of the first scanning apparatus, and a first distance; and selecting a corresponding first distance from the distribution set of sizes of cross sections when the sizes of the receiving cross sections are symmetrically distributed relative to an angle of the first scanning apparatus.

According to a second aspect, this application provides a scanning surface placement apparatus, including a processor, a memory, and a communications interface, where the processor is connected to the memory and the communications interface; the memory is configured to store executable program code; and the processor reads executable program code stored in the memory to run a program corresponding to the executable program code, to perform the foregoing scanning apparatus placement method.

According to a third aspect, this application provides a computer-readable storage medium, storing a computer program, where when the program is executed by a processor, the foregoing scanning apparatus placement method is implemented.

In the scanning apparatus placement method provided in the present disclosure, the calculation model of the receiving cross section of the second scanning surface is established, the sizes of the receiving cross sections with different rotation angles of the first scanning apparatus and different values of the first distances are calculated, and then the distribution set of sizes of cross sections corresponding to the size of the receiving cross section, the rotation angle of the first scanning apparatus, and the first distance is further obtained; and the corresponding first distance is selected for the placement position of the second scanning apparatus from the distribution set of sizes of cross sections when the sizes of the receiving cross sections are symmetrically distributed relative to the rotation angle of the first scanning apparatus, to implement the maximum size of the receiving cross section when the laser beam is at a center of the field of view, so that the receiving cross sections formed when the laser beams are symmetrically located on left and right sides of the center of the field of view have the same size, which resolves the technical problem that the point cloud of the LiDAR deteriorates due to unreasonable placement positions of the existing first scanning apparatus and second scanning apparatus, thereby ensuring that the LiDAR can obtain better point cloud data and have the same ranging performance on the left and right sides horizontally.

### BRIEF DESCRIPTION OF DRAWINGS

To explain the technical solution in embodiments in the present disclosure, the following briefly introduces the accompanying drawings for description in the embodiments. Obviously, the accompanying drawings in the following description are only some embodiments in the present disclosure.

FIG. 1 is a schematic diagram of detection of a first scanning apparatus and a second scanning apparatus when a laser beam is at a center of a field of view;

FIG. 2 is a schematic diagram of detection of a first scanning apparatus and a second scanning apparatus when a laser beam is on a right side of a center of a field of view;

FIG. 3 is a schematic diagram of detection of a first scanning apparatus and a second scanning apparatus when a laser beam is on a left side of a center of a field of view;

FIG. 4 is a flowchart of a scanning apparatus placement method according to an embodiment;

FIG. 5 is a schematic diagram of a planar geometric model of a first scanning apparatus and a second scanning apparatus;

FIG. 6 is a flowchart of establishing a calculation model of a receiving cross section in a scanning apparatus placement method;

FIG. 7 is a schematic diagram of a boundary condition in a scanning apparatus placement method;

FIG. 8 is another schematic diagram of a boundary condition in a scanning apparatus placement method;

FIG. 9 is a schematic cross-sectional view of a first scanning apparatus according to an embodiment;

FIG. 10 is a schematic diagram of a distribution set of sizes of cross sections in a scanning apparatus placement method; and

FIG. 11 is a schematic diagram of a scanning surface placement apparatus. Reference signs in figures:
X—first direction; Y—second direction;
10—laser beam;
20—first scanning apparatus; 21—first scanning surface;
30—second scanning apparatus; 31—second scanning surface; and
41—processor; 42—memory; 43—input apparatus; 44—output apparatus.

### DETAILED DESCRIPTION

The embodiments of the present disclosure are described in detail below. Examples of the embodiments are shown in the accompanying drawings, and the same or similar reference signs indicate the same or similar elements or elements with the same or similar functions. The embodiments described below with reference to the drawings are exemplary and intended to explain the present disclosure, but cannot be construed as a limitation on the present disclosure.

Referring to “an embodiment” or “embodiments” throughout this specification means that a specific feature, structure, or characteristic described with reference to the embodiment is included in at least one embodiment of this application. Therefore, the phrase “in an embodiment” or “in some embodiments” appearing throughout the specification does not always refer to a same embodiment. In addition, a specific feature, structure, or characteristic may be combined in any appropriate manner in one or more embodiments.

In the description of the present disclosure, it should be understood that azimuth or position relationships indicated by terms such as “length,” “width,” “above,” “under,” “front,” “rear,” “left,” “right,” “vertical,” “horizontal,” “top,” “bottom,” “inner,” and “outer” are based on the azimuth or position relationships shown in the accompanying drawings, are merely intended to describe the present disclosure and simplify the descriptions, but are not intended to indicate or imply that the specified device or element shall have specific azimuth or be formed and operated in specific azimuth, and therefore cannot be understood as a limitation on the present disclosure.

In addition, the terms such as “first” and “second” are merely intended for the purpose of description, and shall not be understood as an indication or implication of relative importance or implicit indication of a quantity of indicated technical features. Therefore, a feature with a determiner such as “first” or “second” may expressly or implicitly include one or more features. In addition, terms “include,” “have,” and any variant thereof are intended to cover non-exclusive inclusion. For example, a process, a method, a system, a product, or a device that includes a series of steps or units is not limited to the listed steps or units, but further includes an unlisted step or unit, or further includes another inherent step or unit of the process, the method, the product, or the device.

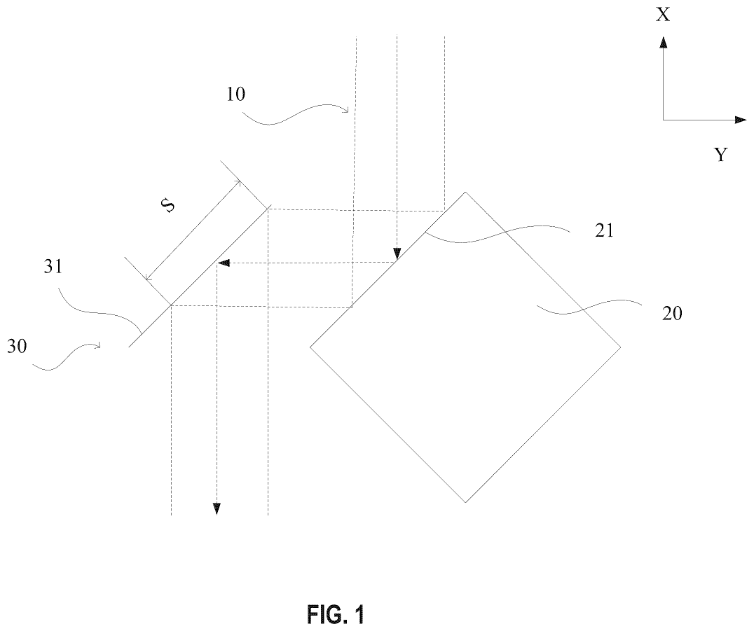

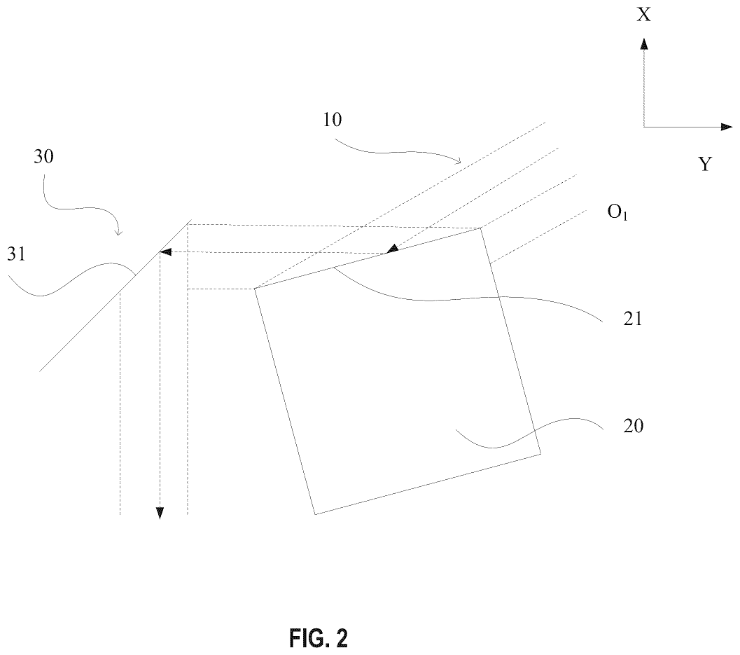

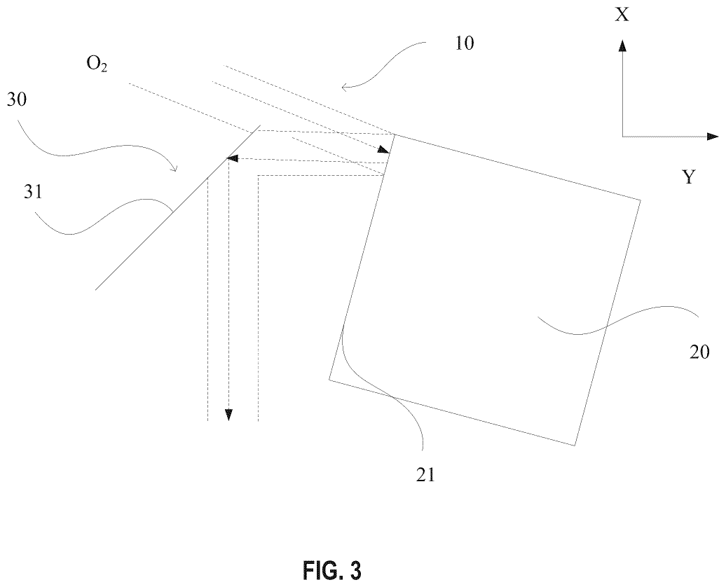

Referring to FIG. 1, an implementation solution of a current mainstream LiDAR is to perform hybrid scanning by combining a second scanning apparatus 30 and a first scanning apparatus 20. On an optical path of an echo beam, the second scanning apparatus 30 is located downstream of an optical path of the first scanning apparatus 20, and the first scanning apparatus 20 has a first scanning surface 21. The first scanning surface 21 is configured to reflect a laser beam 10 incident on the first scanning surface to the second scanning apparatus 30, to implement scanning of the laser beam 10. Because the scanning method is based on reflection, the maximum range of a scanning field of view (FOV) in the scanning method does not exceed 180°. For automotive LiDAR, an angle of view in the horizontal direction needs to be greater than 120°. As shown in FIG. 1, when the laser beam 10 is at a center of the horizontal field of view, a size S of the receiving cross section of the second scanning apparatus 30 is the maximum. As shown in FIG. 2, when the laser beam 10 is on a side of the horizontal field of view that is farther away from the second scanning apparatus 30, the first scanning apparatus 20 rotates towards the laser beam 10 to receive the laser beam 10, where a partial laser beam 01 in the laser beam 10 is blocked by the first scanning apparatus 20, which reduces a size of a receiving cross section of the second scanning apparatus 30. As shown in FIG. 3, when the laser beam 10 is on a side of the horizontal field of view that is closer to the second scanning apparatus 30, the first scanning apparatus 20 rotates towards the laser beam 10 to receive the laser beam 10, where a partial laser beam 02 in the laser beam 10 is blocked by the second scanning apparatus 30, which reduces a size of a receiving cross section of the second scanning apparatus 30. When the laser beams 10 are on two sides of the center of the field of view, the sizes of the receiving cross sections are reduced due to different physical reasons (that is, a physical reason that the laser beams 10 are blocked by the first scanning apparatus 20 and a physical reason that the laser beams 10 are blocked by the second scanning apparatus 30 respectively), the related art does not involve how to adjust placement positions of the first scanning apparatus 20 and the second scanning apparatus 30, and as a result, the sizes of the receiving cross sections on two sides of the center of the field of view are asymmetrical, and the entire LiDAR has different ranging performance on left and right sides horizontally, thereby deteriorating a point cloud.

Therefore, an embodiment of the present disclosure provides a scanning apparatus placement method for determining a first scanning apparatus 20 and a second scanning apparatus 30 on the same horizontal plane, where the first scanning apparatus 20 has a first scanning surface 21, and the second scanning apparatus 30 has a second scanning surface 31, where the method is used to determine a first distance M between a center of the first scanning surface 21 and a center of the second scanning surface 31 in a first direction. In some embodiments, the first scanning apparatus 20 is a rotating mirror, and the second scanning apparatus 30 is a galvanometer. In some other embodiments, both the first scanning apparatus 20 and the second scanning apparatus 30 may be rotating mirrors, or both the first scanning apparatus 20 and the second scanning apparatus 30 may be galvanometers. Specific types and scanning methods of the first scanning apparatus 20 and the second scanning apparatus 30 are not limited in this application, and scanning directions corresponding to the first scanning apparatus 20 and the second scanning apparatus 30 are not limited in this application. In some embodiments, the first scanning apparatus 20 may also be a combination of multiple scanning surfaces operating synchronously when driven by a drive apparatus. The second scanning apparatus 30 may also be a combination of multiple scanning surfaces operating synchronously when driven by a drive apparatus. Numbers of scanning surfaces specifically included in the first scanning apparatus 20 and the second scanning apparatus 30 are not limited in this application.

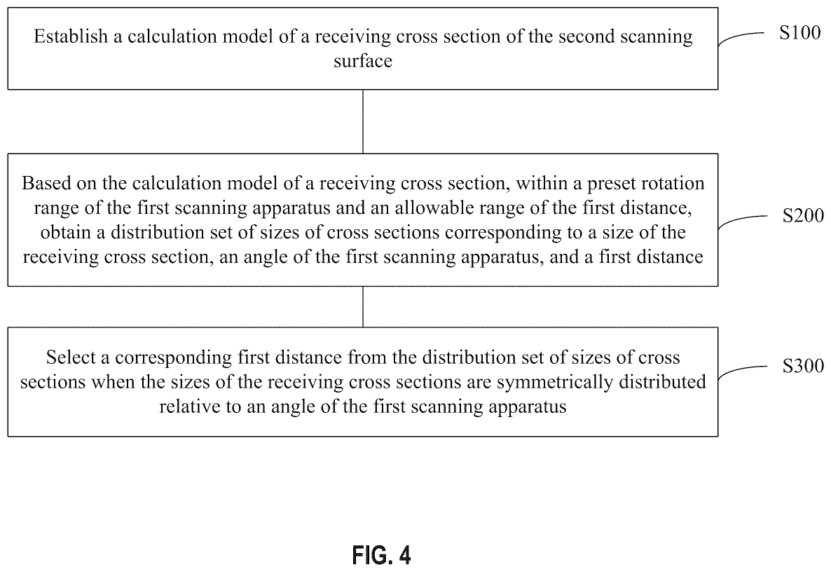

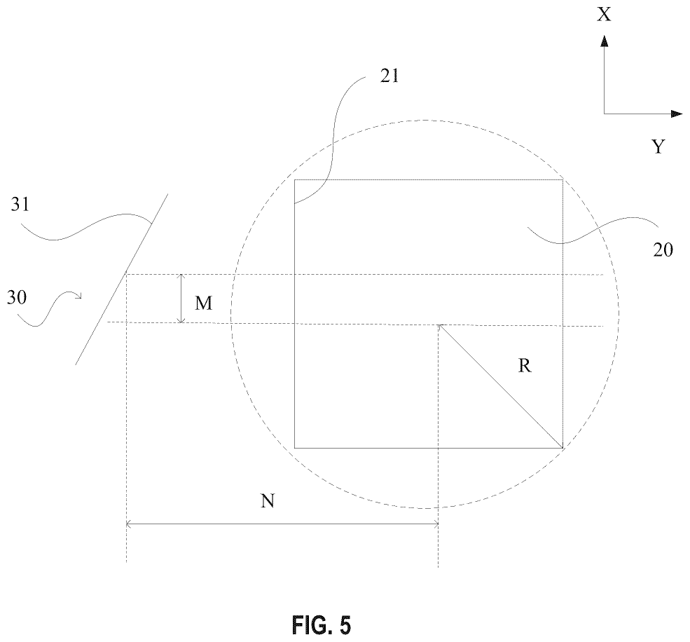

FIG. 4 is a flowchart of a scanning apparatus placement method according to an embodiment. FIG. 5 is a schematic diagram of a planar geometric model of a second scanning apparatus 30 and a first scanning apparatus 20. On an optical path of an echo beam shown in FIG. 5, the first scanning apparatus 20 is located upstream of an optical path of the second scanning apparatus 30, and the first scanning surface 21 of the first scanning apparatus 20 is configured to reflect a laser beam 10 incident on the first scanning surface to the second scanning surface 31 of the second scanning apparatus 30. The method includes the following steps:

S100. Establish a calculation model of a receiving cross section of the second scanning surface 31. The calculation model of a receiving cross section is based on geometric structures and relative positions of the first scanning apparatus 20 and the second scanning apparatus 30, and a reflection principle of light, and can be used to obtain a receiving cross section of the laser beam 10 when the laser beam is incident on the first scanning surface 21 of the first scanning apparatus 20 and then is reflected to the second scanning surface 31 of the second scanning apparatus 30, thereby calculating a size of the receiving cross section.

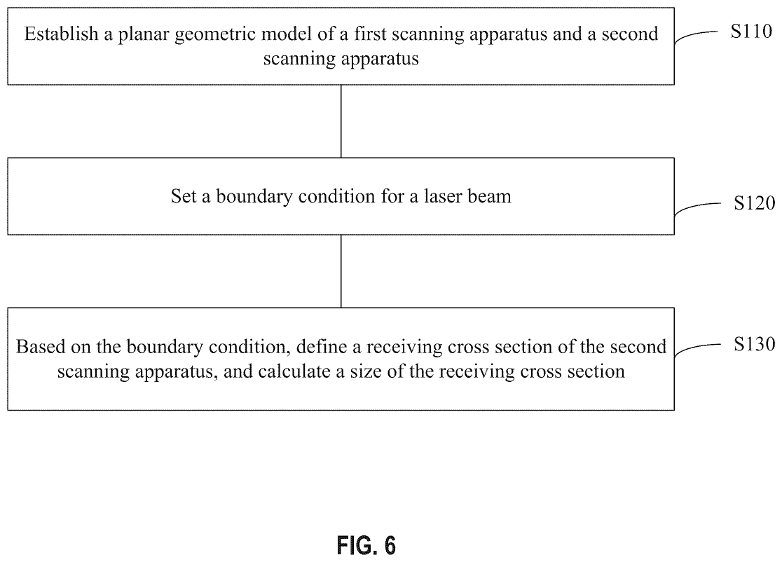

Referring to FIG. 6, step S100 includes:

S110. Establish a planar geometric model of a first scanning apparatus 20 and a second scanning apparatus 30.

First, referring to FIG. 5, a radius of a circle circumscribed on the first scanning apparatus 20 is set to R, a rotation angle of the first scanning apparatus 20 is set to 0, and in this case, a normal direction of the first scanning surface 21 of the first scanning apparatus 20 is the same as the second direction Y, the first scanning surface 21 is on a side of the first scanning apparatus 20 that is closer to the second scanning apparatus 30, and initial values of a first distance M and a second distance N are set. For example, the first distance M is set to 0 and the second distance N is set to 50 mm, to establish the general geometric model.

The second distance N is a distance between a center of the first scanning apparatus 20 and a center of the second scanning apparatus 30 in a second direction Y, and the first direction X and the second direction Y are perpendicular to each other and are on the horizontal plane at which the first scanning apparatus 20 and the second scanning apparatus 30 are located.

In some embodiments, when the general geometric model is established, initial rotation angles of the first scanning apparatus 20 can be set to 10°, 20°, 30°, or 45°, the first distance M can be set to 1 mm, −1 mm, 2 mm, or −2 mm, and the second distance N can be set to 30 mm, 40 mm, 50 mm, or 60 mm.

Then the size information of the first scanning apparatus 20, the size information of the second scanning apparatus 30, the initial value of the first distance M, and the second distance N are obtained, and inputted into the general geometric model, to obtain a planar placement model of the first scanning apparatus 20 and the second scanning apparatus 30.

In some embodiments, when the first scanning apparatus 20 is the rotating mirror and the rotating mirror has two or more than two reflecting surfaces (that is, scanning surfaces), the size information of the first scanning apparatus 20 includes the number of surfaces of the first scanning apparatus 20, the actual radius R of the circle circumscribed on the first scanning apparatus 20 and the initial rotation angle of the first scanning apparatus 20. The initial rotation angle can be set to 0.

The scanning apparatus placement method provided in the embodiments of this application is applicable to a first scanning apparatus 20 with a different number of surfaces. That is, the scanning apparatus placement method does not specifically depend on the number of surfaces of the first scanning apparatus 20. Likewise, the method is applicable to a second scanning apparatus 30 with a different number of surfaces. That is, the method does not specifically depend on the number of surfaces of the second scanning apparatus 30.

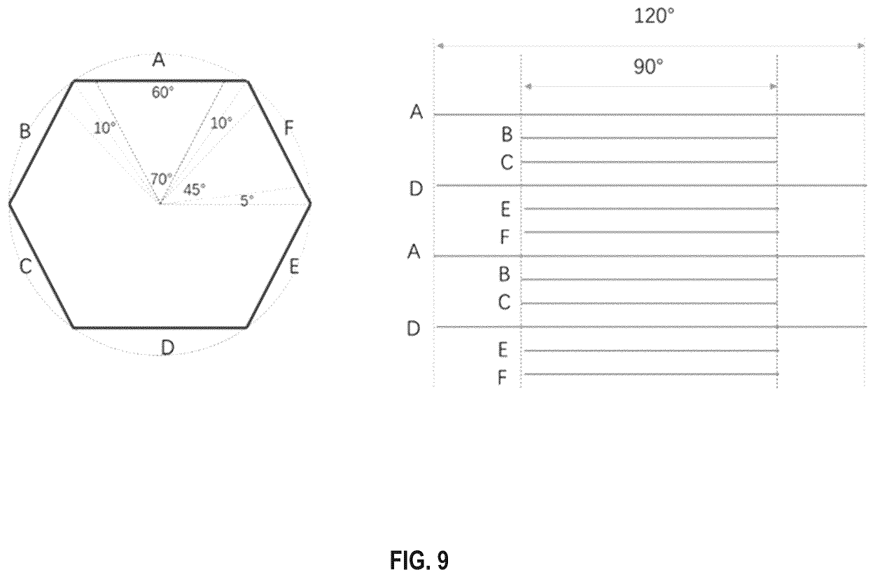

The number of surfaces of the first scanning apparatus 20 is one, two, or more than two. When the first scanning apparatus 20 has more than two scanning surfaces, the scanning surface with the maximum size in the horizontal plane is selected as the first scanning surface 21. FIG. 9 is a schematic cross-sectional view of an irregular six-sided rotating mirror. That is, the first scanning apparatus is an irregular six-sided rotating mirror, where a cross section of the six-sided mirror is a plane perpendicular to an axis of rotation of the six-sided mirror. The divergence angle of the scanning surface corresponding to the center of the rotating mirror is a divergence angle of a side of the scanning surface on the cross section of the rotating mirror corresponding to a center of a circle circumscribed on the cross section of the rotating mirror. At least two adjacent scanning surfaces included in the multiple scanning surfaces correspond to unequal divergence angles at the center of the rotating mirror. In addition, the at least two adjacent scanning surfaces in the multiple scanning surfaces correspond to unequal side lengths on the cross section. For example, as shown in FIG. 9, divergence angles of scanning surface A and scanning surface F are different, and the scanning surface A and the scanning surface F correspond to unequal side lengths on the cross section. That is, different scanning surfaces of the first scanning apparatus 20 have incompletely equal sizes in the cross section. Different scanning surfaces of the irregular rotating mirror correspond to different detection fields of view of the LiDAR. The divergence angle of the scanning surface corresponding to the center of the rotating mirror is a sum of half of an angle of view of the total detection field of view and a set redundant angle. That is, as shown in FIG. 9, a detection angle of view corresponding to surface A is 120°, and a detection angle of view corresponding to surface F is 90°. When the first scanning apparatus 20 is the irregular rotating mirror, a scanning surface with the maximum length should be selected as the first scanning surface 21 (that is, the surface A in FIG. 9), to ensure that the laser beams 10 are located at a center of the maximum detection field of view of the LiDAR, that is, the receiving cross section of the total detection field of view of the LiDAR has the maximum size, and receiving cross sections formed when the laser beams 10 are symmetrically located on two sides of the center of the field of view have the same size, thereby ensuring the same ranging performance on the left and right sides of the total detection field of view of the LiDAR. Similarly, when the second scanning apparatus 30 has more than two scanning surfaces, a scanning surface with the maximum size in the horizontal plane is selected as the second scanning surface 31.

In some embodiments, the second scanning apparatus 30 is a one-dimensional galvanometer. Size information of the second scanning apparatus 30 includes length of the one-dimensional galvanometer. The second scanning apparatus 30 may be a mechanical resonant galvanometer or a MEMS galvanometer.

In an actual LiDAR product, due to a mounting limitation of an internal structure, the second distance N between the first scanning apparatus 20 and the second scanning apparatus 30 is a fixed value and can be obtained directly.

In embodiments of this application, in the method, the general geometric model is established, specific geometric sizes of the first scanning apparatus 20 and the second scanning apparatus 30 are not limited, a specific second distance N is not limited, and therefore, the method is highly versatile. When the specific first distance M between the first scanning apparatus 20 and the second scanning apparatus 30 needs to be calculated, the size information of the first scanning apparatus 20, the size information of the second scanning apparatus 30, the initial value of the first distance M, the second distance N, and a horizontal detection angle of view are inputted into the general geometric model, to obtain a specific planar placement model of the first scanning apparatus 20 and the second scanning apparatus 30, thereby facilitating subsequent calculation of an optimal solution of the first distance M.

S120. Set a boundary condition for a laser beam 10. In an example, in the boundary condition, preset redundancy is retained, thereby reducing stray light in a cavity caused when a light spot is incident at a boundary position. Magnitude of the redundancy depends on the size of the light spot, the length of the first scanning surface 21 and the length of the second scanning surface 31. The larger the light spot, the larger the preset redundancy; and the larger the proportion of the light spot to the entire scanning surface, the larger the preset redundancy that needs to be set. In some embodiments, the preset redundancy is 0.5 to 2 times a radius of the light spot.

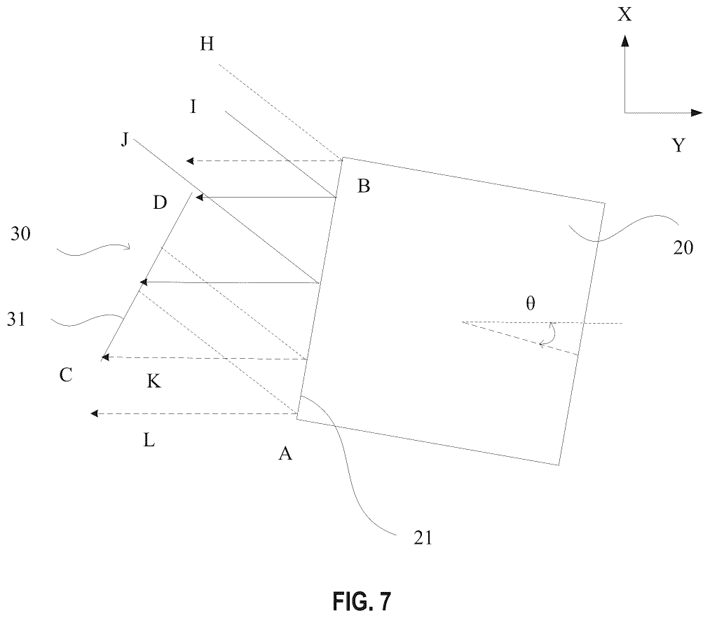

In some embodiments, referring to FIG. 7, assuming that the first scanning surface 21 has a first terminal A and a second terminal B sequentially distributed along the first direction X and the second scanning surface 31 has a third terminal C and a fourth terminal D sequentially distributed along the first direction X, the laser beam 10 has a first side and a second side sequentially distributed along the first direction X. The laser beam 10 may be a pulse laser beam. In some embodiments, the laser beam 10 may be other detection light. This is not specifically limited herein.

In some embodiments, boundary conditions include boundary conditions for the first side and boundary conditions for the second side.

The boundary conditions for the first side include:

Condition 1: When the laser beam is incident, the first side of the laser beam 10 is on a side of the fourth terminal D farther away from the third terminal C, that is, when the laser beam is incident, the first side of the laser beam 10 is on an outer side of the second scanning surface 31, and is not blocked by the second scanning surface 31. In addition, when the laser beam 10 is incident, the fourth terminal D is excluded for the first side the laser beam 10, to retain redundancy and reduce the stray light in the cavity that is caused by the light spot. Referring to FIG. 7, the boundary conditions define a boundary beam J. The boundary beam J satisfies the condition that when being incident, the laser beam is located on the side of the fourth terminal D farther away from the third terminal C, and is located on a first side of the laser beam 10. That is, the boundary beam J is not blocked by the second scanning apparatus 30, and is closer to the first side of the laser beam 10 than boundary beams H and I. In condition 1, when being incident, the laser beam is not required to be located at the fourth terminal D, to retain redundancy and reduce the stray light in the cavity that is caused by the light spot.

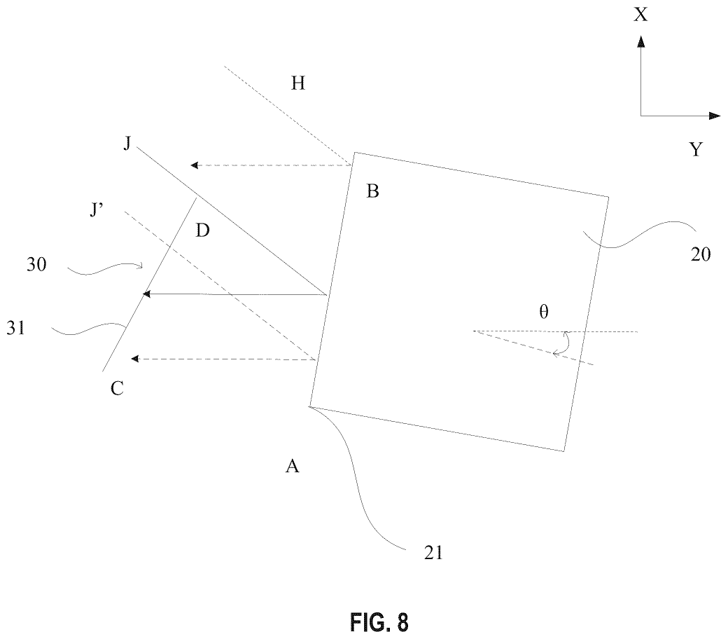

Referring to FIG. 8, another boundary beam J′ is closer to the first side of the laser beam 10 than the boundary beam J, but the boundary beam J′ is located at a side of the fourth terminal D closer to the third terminal C when being incident, does not satisfy the condition 1 in the first boundary conditions, and therefore, cannot be incident on the first scanning surface 21. Therefore, the boundary beam J satisfies the condition 1 in the first boundary conditions and is closest to the first side of the laser beam 10.

In some embodiments, based on a positional relationship between the first side of the laser beam 10, the third terminal C and the fourth terminal D when the laser beam 10 is incident, it can be determined whether a boundary of the first side of the laser beam 10 is blocked by the second scanning apparatus 30, to facilitate screening of the boundary beam on the first side of the laser beam 10. A determining rule is simple and can be easily understood and performed by an operator, or it is easy to convert the determining rule into a machine language for the machine to automatically recognize and execute, thereby reducing difficulty of implementing the method.

Condition 2: When the laser beam is incident, the first side of the laser beam 10 is on a side of the first terminal A closer to the second terminal B, that is, the first side is on the first scanning surface 21. Referring to FIG. 7, the boundary conditions define a boundary beam L. In a case of excluding the condition 1, when being incident, the boundary beam L is on the side of the first terminal A closer to the second terminal B, so that the boundary beam L can be incident on the first scanning surface 21.

Condition 3: When the laser beam is reflected, the first side of the laser beam 10 is on a side of the third terminal C closer to the fourth terminal D. Referring to FIG. 7, the boundary conditions define a boundary beam K. When being reflected, the boundary beam K is on the side of the third terminal C closer to the fourth terminal D, that is, the boundary beam K can be reflected to the second scanning surface 31 of the second scanning apparatus 30, to form an effective echo beam. It can be understood that if the first side of the laser beam 10, for example, the boundary beam L in FIG. 7, is on a side of the third terminal C farther away from the fourth terminal D when being reflected, the first side does not satisfy the condition 3 in the first boundary conditions.

The boundary conditions for the second side include:

Condition 1: When the laser beam is incident, the second side of the laser beam 10 is on a side of the second terminal B closer to the first terminal A. Referring to FIG. 7, the boundary conditions define a boundary beam H. When being reflected, the boundary beam H is on the side of the second terminal B closer to the first terminal A, that is, the boundary beam H can be incident on the first scanning surface 21.

Condition 2: When the laser beam is reflected, the second side of the laser beam 10 is on a side of the fourth terminal D closer to the third terminal C. Referring to FIG. 7, the boundary conditions define a boundary beam I. When being reflected, the boundary beam I is on the side of the fourth terminal D closer to the third terminal C, that is, the boundary beam I can be reflected to the second scanning surface 31.

S130. Based on the boundary condition, define a receiving cross section of the second scanning apparatus 30, and calculate a size of the receiving cross section.

In some embodiments, through step S120 and step S130, the boundary conditions are used to define the receiving cross section of the second scanning apparatus 30, to identify the boundary of the receiving cross section, thereby quickly calculating the size of the receiving cross section.

An exemplary process of calculating the size of the receiving cross section includes the following steps:

Step 1: Referring to FIG. 7, based on the boundary conditions for the first side, obtain three corresponding first boundary beams, namely, the boundary beam J, the boundary beam K, and the boundary beam L.

Step 2: Based on the boundary conditions for the second side, obtain two corresponding second boundary beams, namely, the boundary beam H and the boundary beam I.

Step 3: Select the minimum parallel distance between any one of the three first boundary beams and any one of the two second boundary beams as the size of the receiving cross section.

There are two values for parallel distances between one first boundary beam and two second boundary beams, and there are a total of six values for parallel distances between the three first boundary beams and the two second boundary beams. The minimum value in the six values is the size of the receiving cross section. Referring to FIG. 7, a parallel distance between the boundary beam J in the first boundary beams and the boundary beam I in the second boundary beams is the minimum, and is used as the size of the receiving cross section.

In the method, five boundary beams are obtained based on the boundary conditions, including three first boundary beams and two second boundary beams, and then the minimum value of the calculated six parallel distances is selected as the size of the receiving cross section, without a need of considering all the beams in the laser beams 10 or considering whether all the boundary beams satisfy all the boundary conditions, which greatly simplifies the process of calculating the size of the receiving cross section and improves calculation efficiency.

The parallel distance in this embodiment refers to a distance between two laser beams when the two laser beams are parallel. For example, as shown in FIG. 7, a parallel distance between the boundary beam I and the boundary beam J refers to a distance there between when the boundary beam I and the boundary beam J are incident on the first scanning surface 21 in parallel, or a distance there between when the boundary beam I and the boundary beam J are reflected to the second scanning apparatus 30 in parallel.

To further improve the calculation efficiency, in the method, two simplified solutions for calculating the parallel distance are provided.

First solution for calculating the parallel distance: Calculate a distance between intersection points of any one of the three first boundary beams and any one of the two second boundary beams on a plane at which the first scanning surface 21 is located. In the calculation solution, the distance between intersection points is calculated instead of calculating the distance between parallel lines, thereby improving the calculation efficiency.

Second solution for calculating the parallel distance: Calculate a distance between intersection points of any one of the three first boundary beams and any one of the two second boundary beams on a plane at which the second scanning surface 31 is located. Similarly, in the calculation solution, the distance between the intersection points is calculated, to quickly obtain the size of the receiving cross section.

S200. Based on the calculation model of a receiving cross section, within a preset rotation range of the first scanning apparatus 20 and an allowable range of the first distance M, obtain a distribution set of sizes of cross sections corresponding to a size of the receiving cross section, an angle of the first scanning apparatus 20, and a first distance M.

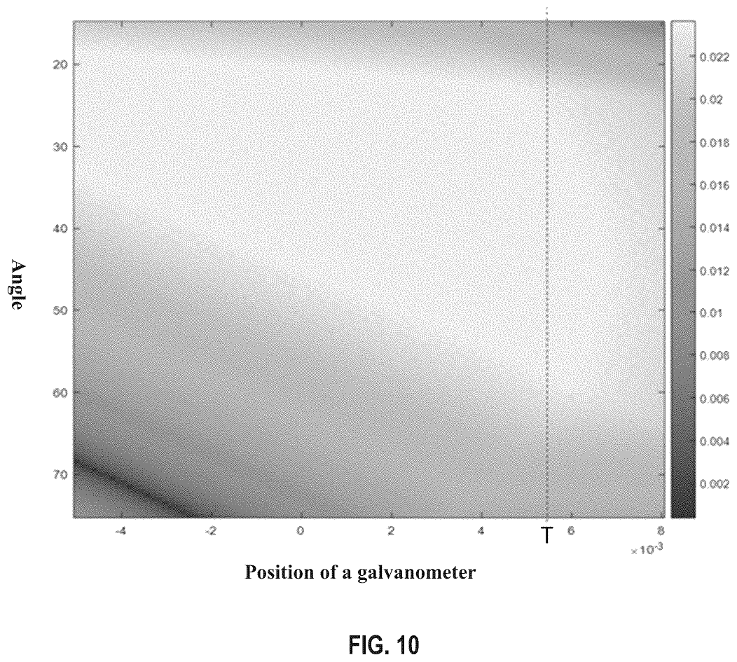

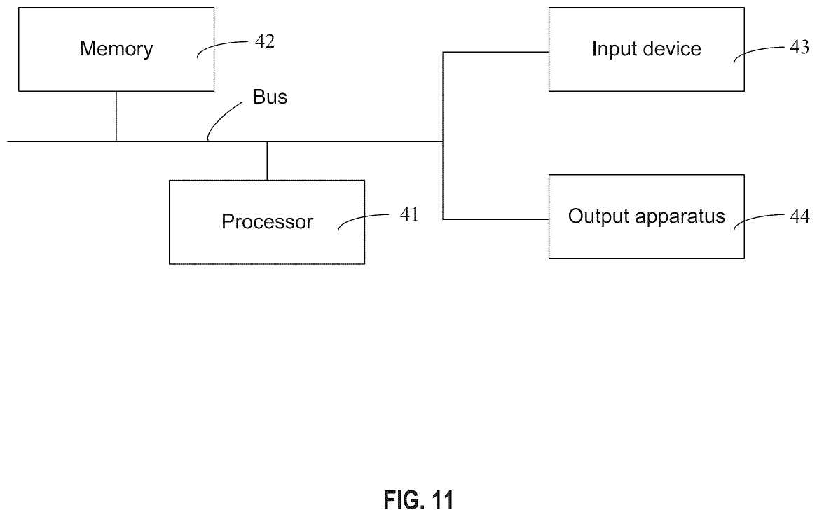

A distribution set of sizes of cross sections can be presented graphically (refer to FIG. 10) or in tabular form.

Steps of obtaining the distribution set of sizes of cross sections include: S210. Perform ergodic assignment on the first distance M based on the allowable range of the first distance M.

S220. Each time the first distance M is assigned, based on the preset rotation range of the first scanning apparatus 20, perform ergodic assignment on a rotation angle of the first scanning apparatus 20.

S230. Each time a rotation angle is assigned for the first scanning apparatus 20, calculate a size of the current receiving cross section.

In this embodiment, an allowable range of the first distance M and a preset rotation range of the first scanning apparatus 20 are traversed, to obtain the distribution set of sizes of receiving cross sections that change along with the angle of the first scanning apparatus 20 and the first distance M.

S300. Select a corresponding first distance M for the placement position of the second scanning apparatus 30 from the distribution set of sizes of cross sections when the sizes of the receiving cross sections are symmetrically distributed relative to an angle of the first scanning apparatus 20.

The “symmetrical” here refers to the most symmetrical distribution of sizes of receiving cross sections selected from the distribution set of sizes of cross sections relative to the angle of the first scanning apparatus 20, which may be symmetrical or roughly symmetrical.

Referring to FIG. 10, in the distribution set of sizes of cross sections, a left ordinate represents the angle of the first scanning apparatus 20, a right ordinate represents the size of the receiving cross section, and the abscissa represents the first distance. Symmetrical distribution of the sizes of the receiving cross sections relative to the angle of the first scanning apparatus 20 is selected from FIG. 10 (refer to a dotted line in FIG. 10). The abscissa corresponding to the dotted line T is the first distance M to be calculated.

In some embodiments, the calculation model of the receiving cross section is established, and the sizes of the receiving cross sections with different rotation angles of the first scanning apparatus 20 and different values of the first distances M are calculated, to obtain the distribution set of sizes of cross sections corresponding to the size of the receiving cross section, the angle of the first scanning apparatus 20, and the first distance M. The corresponding first distance M is selected for the placement position of the second scanning apparatus 30 from the distribution set of sizes of cross sections when the sizes of the receiving cross sections are symmetrically distributed relative to the angle of the first scanning apparatus 20, to implement the maximum size of the receiving cross section when the laser beams 10 are at the center of the field of view, so that the receiving cross sections formed when the laser beams 10 are symmetrically located on left and right sides of the center of the field of view have the same size, thereby ensuring that the LiDAR can obtain better point cloud data and have the same ranging performance on the left and right sides horizontally.

In conclusion, the scanning apparatus placement method provided in embodiments of this application has the following advantages:

First, the placement positions of the first scanning apparatus 20 and the second scanning apparatus 30 on the horizontal plane can be determined.

Second, when the laser beams 10 are at the center of the field of view, the maximum receiving cross section of the second scanning apparatus 30 is retained.

Third, when the laser beams 10 are on the left and right sides of the center of the field of view, the size of the receiving cross section is symmetrical or nearly symmetrical relative to the center of the field of view, thereby helping obtain better point cloud data.

Fourth, the method is applicable to a first scanning apparatus 20 with any number of surfaces and is highly versatile.

### Embodiment 2

Referring to FIG. 11, this application provides a scanning surface placement apparatus, including a processor 41 and a memory 42 communicatively connected with the processor 41. The memory 42 is configured to store executable program code. The processor 41 reads executable program code stored in the memory 42 to run a program corresponding to the executable program code, to perform the foregoing scanning apparatus placement method.

The foregoing scanning apparatus placement method can be stored as executable program code that can be run by a program such as Python or MATLAB.

The processor 41 is, for example, a CPU. The memory 42 may be a high-speed RAM memory 42, or a non-volatile memory (non-volatile memory) 42, such as at least one magnetic disk memory 42.

The scanning surface placement apparatus may further include an input apparatus 43 and an output apparatus 44. The processor 41, the memory 42, the input apparatus 43 and the output apparatus 44 may be connected via a bus or in other manners. In FIG. 11, a bus connection is taken as an example.

The input apparatus 43 may receive input digital or character information, and generate keyboard signal input related to user setting and function control of an apparatus for placing a rotating mirror and a galvanometer, and the input apparatus 43 is, for example, a touchscreen, a keypad, a mouse, a trackpad, a touchpad, a pointer rod, or one or more mouse buttons, trackballs, or joysticks. The output apparatus 44 may include a display device, an auxiliary illuminating apparatus (for example, a LED), a tactile feedback apparatus (for example, a vibration motor), or the like. The display device may include, but is not limited to, a liquid crystal display, a light emitting diode display, and a plasma display. In some embodiments, the display device may also be a touch screen.

### Embodiment 3

This application provides a computer-readable storage medium, storing a computer program, where when the program is executed by a processor 41, the foregoing scanning apparatus placement method is implemented.

An embodiment of this application further provides a computer-readable storage medium, where the computer-readable storage medium stores an instruction, and when running on the computer or the processor 41, the instruction enables the computer or the processor 41 to perform one or more steps in any one of the foregoing methods.

All or some of the foregoing embodiments may be implemented by software, hardware, firmware, or any combination thereof. When software is used to implement the embodiments, the embodiments may be implemented completely or partially in the form of a computer program product. The computer program product includes one or more computer instructions. When the computer program instructions are loaded and executed on the computer, the procedures, or the functions according to the embodiments of this application are all or partially generated. The computer may be a general-purpose computer, a special-purpose computer, a computer network, or other programmable apparatuses. The computer instruction may be stored in a computer readable storage medium, or may be transmitted by using the computer-readable storage medium. The computer instructions may be transmitted from a web site, computer, server, or data center to another web site, computer, server, or data center in a wired (for example, a coaxial cable, an optical fiber, or a digital subscriber line (DSL)) or wireless (for example, infrared, radio, and microwave, or the like) manner. The computer-readable storage medium may be any usable medium accessible to a computer, or a data storage device, such as a server or a data center, integrating one or more usable media. The usable medium may be a magnetic medium (for example, a floppy disk, a hard disk, or a magnetic tape), an optical medium (for example, a digital video disc (DVD), a semiconductor medium (for example, a solid state disk (SSD)), or the like.

All or some of the processes of the methods in the embodiments may be implemented by a computer program instructing relevant hardware. The program may be stored in a computer readable storage medium. When the program is executed, the processes of the methods in the embodiments are performed. The foregoing storage medium includes: various media that can store program code, such as a read-only memory (ROM), a random access memory (RAM), a magnetic disk, or an optical disc. In absence of conflicts, the embodiments and features in the embodiments may be randomly combined.

What is claimed is:

1. A method of scanning apparatus placement, applied to a first scanning apparatus and a second scanning apparatus on the same horizontal plane, wherein the first scanning apparatus has a first scanning surface, and the second scanning apparatus has a second scanning surface, wherein the method is used to determine a first distance between a center of the first scanning surface and a center of the second scanning surface in a first direction, and comprises:
establishing a calculation model of a receiving cross section of the second scanning surface;
based on the calculation model of a receiving cross section, within a preset rotation range of the first scanning apparatus and an allowable range of the first distance, obtaining a distribution set of sizes of cross sections corresponding to an angle of the first scanning apparatus, and a first distance; and
selecting a corresponding first distance from the distribution set of sizes of cross sections, when the sizes of the receiving cross sections are symmetrically distributed relative to an angle of the first scanning apparatus.

2. The method according to claim 1, wherein establishing the calculation model of the receiving cross section comprises:
establishing a planar geometric model of the first scanning apparatus and the second scanning apparatus;
setting a boundary condition for a laser beam; and
based on the boundary condition, defining a receiving cross section of the second scanning apparatus, and calculating a size of the receiving cross section.

3. The method according to claim 2, wherein on an optical path of an echo beam, the first scanning apparatus is located upstream of an optical path of the second scanning apparatus, the first scanning surface is configured to reflect a laser beam incident on the first scanning surface to the second scanning surface, the first scanning surface has a first terminal and a second terminal sequentially distributed along the first direction, the second scanning surface has a third terminal and a fourth terminal sequentially distributed along the first direction, and the laser beam has a first side and a second side sequentially distributed along the first direction; and
the boundary conditions comprise:
boundary conditions for the first side: (1) when the laser beam is incident, the first side of the laser beam is on a side of the fourth terminal farther away from the third terminal; or (2) when the laser beam is incident, the first side of the laser beam is on a side of the first terminal closer to the second terminal; and (3) when the laser beam is reflected, the first side of the laser beam is on a side of the third terminal closer to the fourth terminal; and
boundary conditions for the second side: (1) when the laser beam is incident, the second side of the laser beam is on a side of the second terminal closer to the first terminal; and (2) when the laser beam is reflected, the second side of the laser beam is on a side of the fourth terminal closer to the third terminal.

4. The method according to claim 3, wherein calculating the size of the receiving cross section comprises:
obtaining three corresponding first boundary beams based on the boundary conditions for the first side;
obtaining two corresponding second boundary beams based on the boundary conditions for the second side; and
selecting the minimum of a parallel distance between any one of the three first boundary beams and any one of the two second boundary beams as the size of the receiving cross section.

5. The method according to claim 4, wherein a method for calculating the parallel distance between any one of the three first boundary beams and any one of the two second boundary beams comprises:
calculating a distance between intersection points of any one of the three first boundary beams and any one of the two second boundary beams on a plane at which the first scanning surface is located.

6. The method according to claim 4, wherein a method for calculating the parallel distance between any one of the three first boundary beams and any one of the two second boundary beams comprises:
calculating a distance between intersection points of any one of the three first boundary beams and any one of the two second boundary beams on a plane at which the second scanning surface is located.

7. The method according to claim 2, wherein establishing the planar geometric model of the first scanning apparatus and the second scanning apparatus comprises:
establishing a general geometric model; and
obtaining size information of the first scanning apparatus, size information of the second scanning apparatus, an initial value of the first distance, and a second distance, and inputting the size information of the first scanning apparatus, the size information of the second scanning apparatus, the initial value of the first distance, and the second distance into the general geometric model, wherein
the second distance is a distance between a center of the first scanning surface and a center of the second scanning surface in a second direction, and the first direction and the second direction are on the horizontal plane and perpendicular to each other.

8. The method according to claim 1, wherein obtaining the distribution set of sizes of cross sections corresponding to a size of the receiving cross section, the angle of the first scanning apparatus, and the first distance comprises:
performing ergodic assignment on the first distance based on the allowable range of the first distance;
each time the first distance is assigned, based on the preset rotation range of the first scanning apparatus, performing ergodic assignment on a rotation angle of the first scanning apparatus; and
each time a rotation angle is assigned for the first scanning apparatus, calculating a size of the receiving cross section in a current placement.

9. The method according to claim 1, wherein when the first scanning apparatus has more than two scanning surfaces, selecting a scanning surface with the maximum size in the horizontal plane as the first scanning surface.

10. The method according to claim 1, wherein when the second scanning apparatus has more than two scanning surfaces, selecting a scanning surface with the maximum size in the horizontal plane as the second scanning surface.

11. A scanning surface placement apparatus, comprising a processor, a memory, and a communications interface, wherein
the processor is connected to the memory and the communications interface;
the memory is configured to store executable program code; and
the processor reads executable program code stored in the memory to run a program corresponding to the executable program code, to perform the method of scanning apparatus placement according to claim 1.

12. A non-transitory computer-readable storage medium, storing a computer program, wherein when the program is executed by a processor, the method of scanning apparatus placement according to claim 1 is implemented.
